(19) United States
(12) Patent Application Publication
(10) Pub. No.: US 2024/0322268 A1
(43) Pub. Date: Sep. 26, 2024

(54) ENERGY STORAGE APPARATUS, AND METHOD OF DIAGNOSING FAILURE OF CURRENT INTERRUPTION DEVICE

(71) Applicant: GS Yuasa International Ltd., Kyoto (JP)

(72) Inventors: Masahiro TATSUMI, Kyoto-shi, Kyoto (JP); Atsushi FUKUSHIMA, Kyoto-shi, Kyoto (JP); Takashi YAMASHITA, Kyoto-shi, Kyoto (JP); Yuki IMANAKA, Kyoto-shi, Kyoto (JP)

(21) Appl. No.: 18/577,830

(22) PCT Filed: Jun. 10, 2022
(86) PCT No.: PCT/JP2022/023401

§ 371 Date: Jan. 9, 2024

(30) Foreign Application Priority Data
Jul. 14, 2021 (JP) 2021-116471

(51) Int. Cl. H01M 10/42; H01M 50/55; H01M 50/569; H01M 50/574

(52) U.S. Cl. CPC H01M 10/4257; H01M 50/55; H01M 50/569; H01M 50/574; H01M 2010/4271

(57) ABSTRACT

An energy storage apparatus 50 includes: a cell 62; positive and negative external terminals 51, 52; a current interruption device 53 disposed on a first line 55P that connects the cell and one of the external terminals; a resistor 54 for current measurement that is disposed on a second line 55N that connects the cell and the other of the external terminals; a discharge circuit 120 connected to the cell 62 and the current interruption device 53 in parallel; and a control device 130. The discharge circuit 120 includes a discharge resistor 121 and a discharge switch 123. The control device 130, in a state where the current interruption device 53 is controlled to take an open state, measures currents I1, I2 by the resistor 54 with respect to a state where the discharge switch 123 is in a closed position and a state where the discharge switch 123 is in an open position, and diagnoses a failure in the current interruption device 53 based on a difference ΔI between a current value I2 measured when the discharge switch 123 is in the closed position and a current value I1 measured when the discharge switch 123 is in the open position.

### CROSS REFERENCE TO RELATED APPLICATIONS

This application is a National Stage Application, filed under 35 U.S.C. § 371, of International Application No. PCT/JP2022/023401, filed Jun. 10, 2022, which international application claims priority to and the benefit of Japanese Application No. 2021-116471, filed July 14, 20; the contents of both of which as are hereby incorporated by reference in their entireties.

### BACKGROUND

### Technical Field

The present invention relates to a technique for diagnosing a failure of a current interruption device.

### Description of Related Art

An energy storage apparatus mounted on an automobile or the like includes a current interruption device such as a relay. When abnormality such as overdischarging or overcharging is detected, the flow of a current is interrupted by opening a current interruption device thus protecting an energy storage apparatus. When a failure occurs in a current interruption device, an energy storage apparatus cannot be protected from overdischarging or overcharging. Accordingly, it is necessary to diagnose the occurrence of a failure in the current interruption device.

Patent document WO2019/208410 discloses a relay failure diagnosis method that includes: a first detection step of opening a first relay at the time of discharging an energy storage apparatus for starting and detecting a current value by a detection unit in a state a second relay is closed; and a determination step of determining the occurrence of a failure in the first relay based on a detection result in the first detection step.

### BRIEF SUMMARY

As one of methods of measuring a current, there has been known a method that uses a resistor. When a current flows through the resistor, a voltage is generated at both ends of the resistor and hence, a current can be measured from the voltage. In a case where a temperature difference exists between both ends of the resistor, a measurement error occurs due to a Seebeck effect. When the accuracy of current measurement is lowered due to a Seebeck effect, there is a possibility that accuracy of diagnosis of a failure in a current interruption device is lowered.

It is an object of one aspect of the present invention is to improve accuracy in determination of a failure in a current interruption device by improving accuracy of current measurement.

An energy storage apparatus includes: a cell; positive and negative external terminals; a current interruption device that is disposed on a first line that connects the cell and one of the positive and negative external terminals; a resistor for current measurement that is disposed on a second line that connects the cell and the other of the positive and negative external terminals; a discharge circuit connected to the cell and the current interruption device in parallel; and a control device.

The discharge circuit includes a discharge resistor and a discharge switch.

The control device is configured, in a state where the current interruption device is controlled to take an open state, to measure a current by the resistor with respect to a state where the discharge switch is controlled to take a closed position and a state where the discharge switch is controlled to take an open position, and to diagnoses a failure in the current interruption device based on a difference between a current value measured in a state where the discharge switch is controlled to take the closed position and a current value measured in a state where the discharge switch is controlled to take the open position.

This technique is also applicable to a method of diagnosing a failure of a current interruption device and program of diagnosing a failure of a current interruption device.

The present technique can enhance the accuracy of diagnosis of a failure in a current interruption device by enhancing accuracy of current measurement.

### BRIEF DESCRIPTION OF THE FIGURES

FIG. 1 is a side view of a vehicle.

FIG. 2 is an exploded perspective view of a battery (an energy storage apparatus).

FIG. 3 is a plan view of a secondary battery cell.

FIG. 4 is a cross-sectional view taken along a line A-A in FIG. 3.

FIG. 5 is a block diagram illustrating an electrical configuration of the battery.

FIG. 6 is a graph illustrating charge characteristics of a battery.

FIG. 7 is a block diagram illustrating a current path in the battery.

FIG. 8 is a block diagram illustrating a current path in the battery.

FIG. 9 is a block diagram illustrating a current path in the battery.

FIG. 10 is an explanatory block diagram for explaining a Seebeck effect.

FIG. 11 is a diagram illustrating a relationship between a current I1 and a current I2 when the current interruption device is normal.

FIG. 12 is a diagram illustrating a relationship between a current I1 and a current I2 when a failure has occurred in a current interruption device.

FIG. 13 is a failure diagnosis sequence of a current interruption device.

FIG. 14 is a block diagram illustrating an electrical configuration of a battery.

### DETAILED DESCRIPTION OF VARIOUS EMBODIMENTS

The overall configuration of an energy storage apparatus will be described.

An energy storage apparatus includes: a cell; positive and negative external terminals; a current interruption device that is disposed on a first line that connects the cell and one of the positive and negative external terminals; a resistor for current measurement that is disposed on a second line that connects the cell and the other of the positive and negative external terminals; a discharge circuit connected to the cell and the current interruption device in parallel; and a control device.

The discharge circuit includes a discharge resistor and a discharge switch.

The control device is configured, in a state where the current interruption device is controlled to take an open state, to measure a current by the resistor with respect to a state where the discharge switch is controlled to take a closed position and a state where the discharge switch is controlled to take an open position, and to diagnoses a failure in the current interruption device based on a difference between a current value measured in a state where the discharge switch is controlled to take the closed position and a current value measured in a state where the discharge switch is controlled to take the open position.

With such a configuration, it is possible to cancel a measurement error caused by a Seebeck effect included in the current value by calculating the difference between the current values. Accordingly, the present technique can suppress lowering of accuracy of current measurement thus enhancing the accuracy of diagnosis of a failure in a current interruption device. With such a configuration, it is possible to detect a failure in the current interruption device at an early stage and hence, and it is possible to urge early replacement of an energy storage apparatus.

The control device may determine that the current interruption device is normal when the difference between the current values is equal to or greater than a threshold. In a case where the difference between the current values is equal to or greater than a threshold, it is possible to determine that a sufficient amount of current flows through the resistor in a state where the discharge switch is closed. That is, in case where the current interruption device is disposed on a positive electrode side of the cell and the resistor is disposed on the negative electrode side, it is possible to determine that a sufficient current flows through a path formed of the external terminal of positive electrode, the discharge circuit, the resistor and the external terminal of negative electrode. Accordingly, it is determined that the current interruption device is normal (open).

The control device may determine that a failure has occurred in the current interruption device in a case where the difference between the current values is less than the threshold. In a case where the difference between the current values is less than the threshold, it can be determined that a sufficient current does not flow through the resistor in a state where the discharge switch is controlled to take a closed position. That is, in a case where the current interruption device is disposed at the positive electrode of the cell and the resistor is disposed at the negative electrode of the cell, it is determined that a sufficient current is not flowing through the path formed of the external terminal of the positive electrode, the discharge circuit, the resistor and the external terminal of the negative electrode. Accordingly, it can be determined that a failure (closing) has occurred in the current interruption device.

### Embodiment 1

### 1. Description of Battery 50

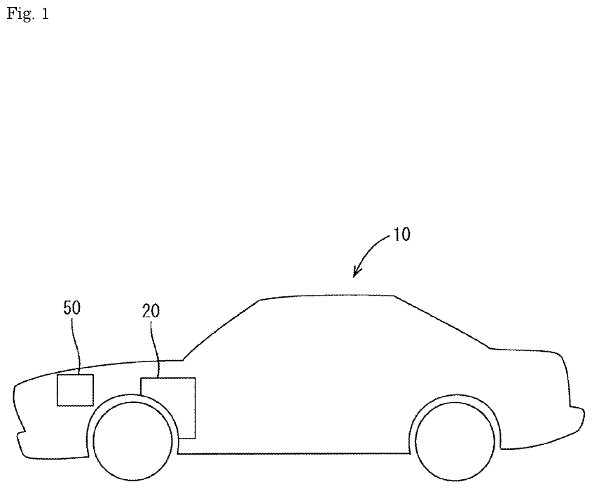

As illustrated in FIG. 1, an engine 20 and a battery 50 that is used for starting the engine 20 and other purposes are mounted on a vehicle 10. The battery 50 is an example of “energy storage apparatus”. On the vehicle 10, in place of the engine 20 (internal combustion engine), an energy storage apparatus or a fuel battery for driving the vehicle may be mounted.

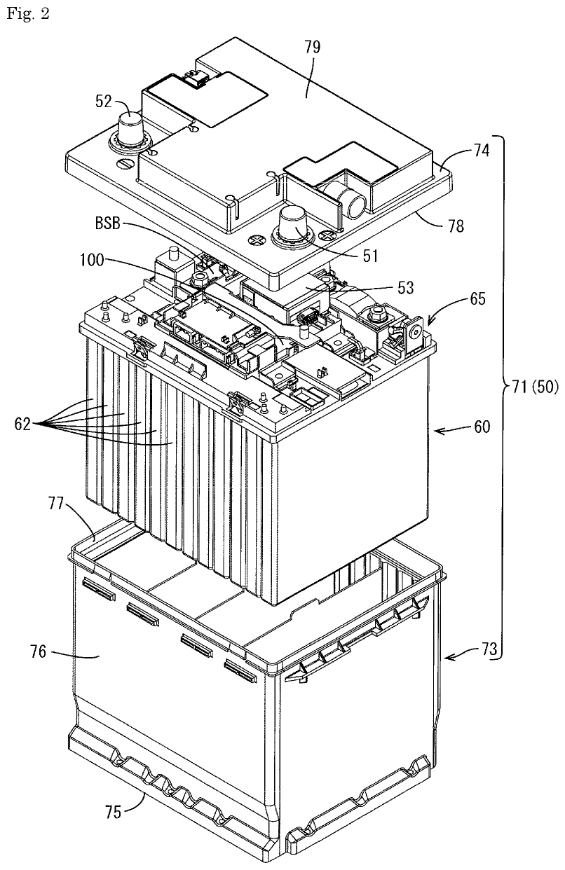

As illustrated in FIG. 2, the battery 50 includes an assembled battery 60, a circuit board unit 65, and a container 71. The container 71 includes: a body 73 made of a synthetic resin material; and a lid body 74. The body 73 has a bottomed cylindrical shape, and includes a bottom surface portion 75 and four side surface portions 76. An opening portion 77 is formed at an upper end of the body 73 by four side surface portions 76.

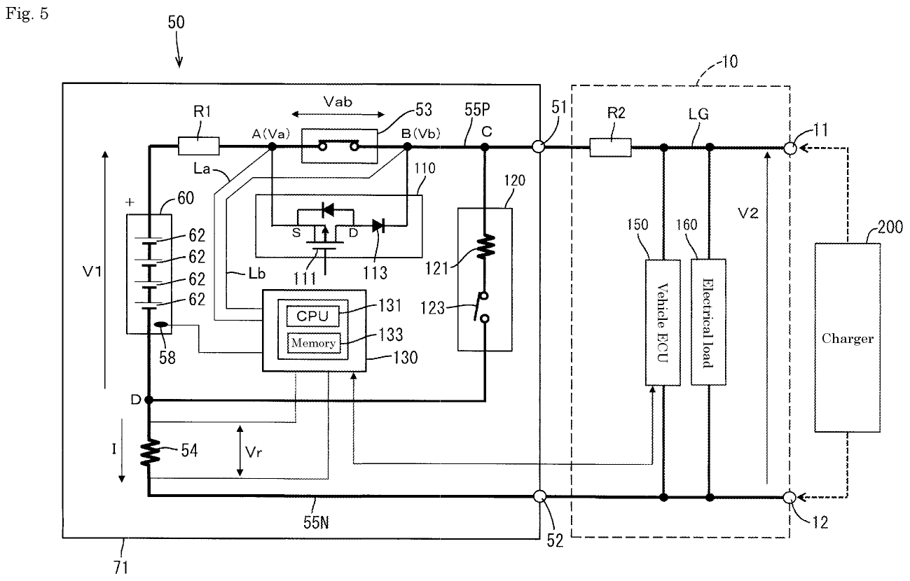

The container 71 contains the assembled battery 60 and a circuit board unit 65. The circuit board unit 65 is a board unit where various components (a current interruption device 53, a shunt resistor 54, a bypass circuit 110, a discharge circuit 120, a management device 130 and the like illustrated in FIG. 5) are mounted on a circuit board 100. As illustrated in FIG. 2, the circuit board unit 65 is disposed, for example, above and adjacently to the assembled battery 60. Alternatively, the circuit board unit 65 may be disposed adjacently to a side of the assembled battery 60.

The lid body 74 closes the opening portion 77 of the body 73. An outer peripheral wall 78 is formed on a periphery of the lid body 74. The lid body 74 has a protruding portion 79 having an approximately T shape as viewed in a plan view. On a front portion of the lid body 74, an external terminal 51 of a positive electrode is fixed to one corner portion, and an external terminal 52 of a negative electrode is fixed to the other corner portion. The circuit board unit 65 may be contained in the lid body 74 (for example, in the protruding portion 79) in place of being contained in the body 73 of the container 71.

The assembled battery 60 is constituted of a plurality of cells 62. As illustrated in FIG. 4, the cell 62 is configured such that an electrode assembly 83 is accommodated in a case 82 having a rectangular parallelepiped shape (a prismatic shape) together with a nonaqueous electrolyte. The cell 62 is, for example, a lithium ion secondary battery cell. The case 82 includes: a case body 84; and a lid 85 that closes an opening portion formed at an upper portion of the case body 84.

Although not illustrated in detail, the electrode assembly 83 is formed such that a separator formed of a porous resin film is disposed between a negative electrode plate that is formed by applying an active material to a substrate formed of a copper foil, and a positive electrode plate that is formed by applying an active material to a substrate formed of an aluminum foil. These elements all have a strip shape, and are wound in a flat shape so as to be accommodated in the case body 84 in a state where the position of the negative electrode plate and the position of the positive electrode plate are displaced toward opposite sides in the width direction with respect to the separator. The electrode assembly 83 may be of a stacked type in place of a wound type.

A positive electrode terminal 87 is connected to the positive electrode plate via a positive electrode current collector 86, and a negative electrode terminal 89 is connected to the negative electrode plate via a negative electrode current collector 88. The positive electrode current collector 86 and the negative electrode current collector 88 are each formed of: a flat plate-like pedestal portion 90; and a leg portion 91 extending from the pedestal portion 90. A through hole is formed in the pedestal portion 90. The leg portion 91 is connected to the positive electrode plate or the negative electrode plate.

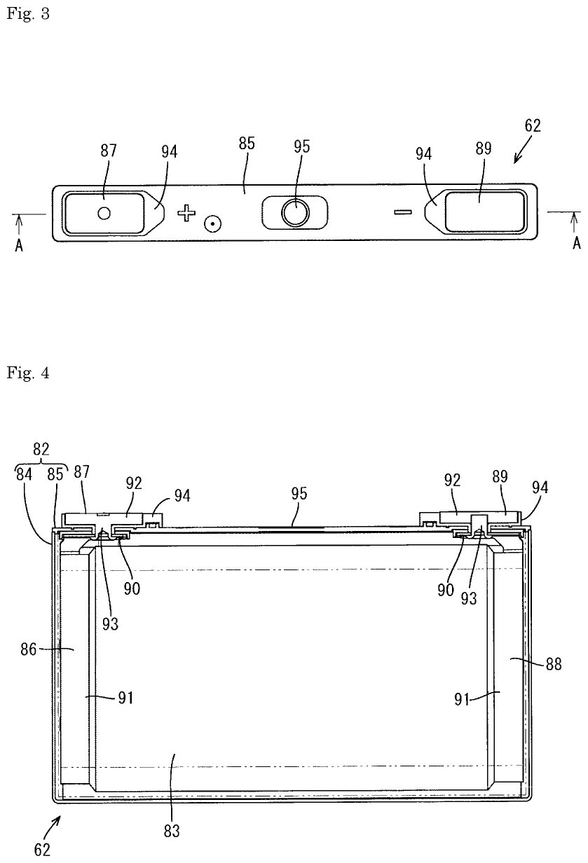

The positive electrode terminal 87 and the negative electrode terminal 89 each include: a terminal body portion 92; and a shaft portion 93 protruding downward from a center portion of a lower surface of the terminal body portion 92. The terminal body portion 92 and the shaft portion 93 of the positive electrode terminal 87 are integrally formed with each other by molding using aluminum (a single material). In the negative electrode terminal 89, the terminal body portion 92 is made of aluminum, and the shaft portion 93 is made of copper. The negative electrode terminal 89 is formed by assembling the terminal body portion 92 and the shaft portion 93 to each other. The terminal body portion 92 of the positive electrode terminal 87 and the terminal body portion 92 of the negative electrode terminal 89 are disposed at both end portions of the lid 85 by way of gaskets 94 made of an insulating material. The terminal body portion 92 of the positive electrode terminal 87 and the terminal body portion 92 of the negative electrode terminal 89 are exposed outward from the gaskets 94 as illustrated in FIG. 3.

The lid 85 has a pressure release valve 95. The pressure release valve 95 is positioned between the positive electrode terminal 87 and the negative electrode terminal 89. The pressure release valve 95 is a safety valve. The pressure release valve 95 is released when an internal pressure in the case 82 exceeds a limit value so as to lower the internal pressure in the case 82.

FIG. 5 is a block diagram illustrating an electrical configuration of the battery 50. The battery 50 includes: the assembled battery 60; the current interruption device 53; a shunt resistor 54; a temperature sensor 58; a bypass circuit 110; a discharge circuit 120; and a management device 130. The management device 130 is an example of “a control device”.

In the battery 50, a vehicle electronic control unit (ECU) 150, an electrical load 160, and an alternator (not illustrated in the drawing) are electrically connected to each other. The vehicle ECU 150 is a vehicle control device that controls the vehicle 10. The vehicle ECU 150 controls the electrical load 160. The vehicle ECU 150 may also control a drive system such as an engine. The number of vehicle ECUs 150 is not limited to one, and may be plural.

In a case where an electricity generation amount of the alternator (not illustrated in the drawing) is larger than an electricity consumption amount of the electrical load 160 during driving of the engine 20, the battery 50 is charged with electricity by the alternator. In a case where the electricity generation amount of the alternator is smaller than the electricity consumption amount of the electrical load 160, the battery 50 discharges electricity to compensate for a shortage of electricity.

In a state where the engine 20 is stopped, the alternator stops the generation of electricity. During the generation of electricity is stopped, the battery 50 is brought into a state where the battery 50 is not charged with electricity. That is, the battery 50 is brought into a state where the battery 50 performs only discharging of electricity to the vehicle ECU 150 and the electrical load 160.

For example, twelve cells 62 (see FIG. 2) of the assembled battery 60 are connected with each other in three parallels and four series. In FIG. 5, three cells 62 that are connected in parallel are indicated by one battery symbol. The cell is not limited to a prismatic cell, and may be a cylindrical cell or a pouch cell having a laminate film case.

The assembled battery 60, the current interruption device 53 and the shunt resistor 54 are connected in series via a power line 55P and a power line 55N. As the power lines 55P, 55N, a bus bar BSB (see FIG. 2) which is a plate-like conductor made of a metal material such as copper can be used.

As illustrated in FIG. 5, the power line 55P connects the positive external terminal 51 and the positive electrode of the assembled battery 60 to each other. The power line 55N connects the negative external terminal 52 and the negative electrode of the assembled battery 60 to each other. The power line 55P is an example of “a first line”, and the power line 55N is an example of a “a second line”.

The external terminals 51 and 52 are terminals for connecting the battery 50 to the automobile 10 (electrical load 160). The battery 50 can be electrically connected to the vehicle ECU 150 or the electrical load 160 via the external terminals 51 and 52.

The current interruption device 53 is provided to the power line 55P on a positive electrode side. The current interruption device 53 may be a semiconductor switch such as an FET or a relay having a mechanical contact. The current interruption device 53 is preferably a self-holding switch such as a latch relay. The current interruption device 53 is of a normally closed type, and is controlled to take a closed state at the time of performing a normal operation. When an abnormality occurs in the battery 50, a current to the assembled battery 60 can be interrupted by changing over the current interruption device 53 from a closed state to an open state.

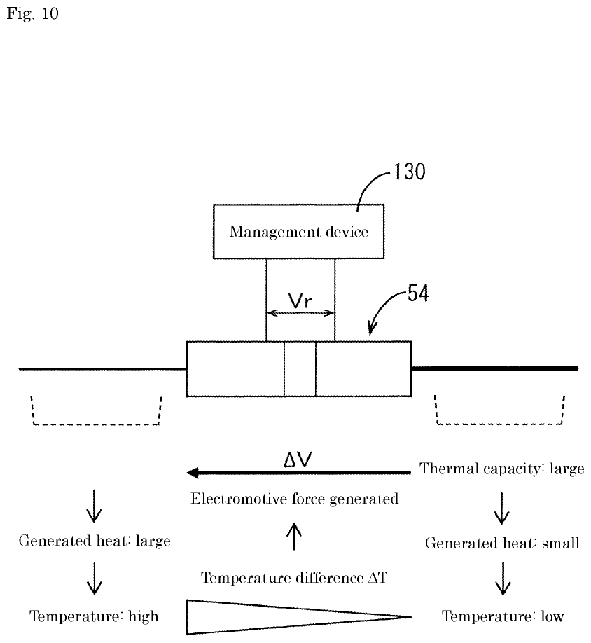

The shunt resistor 54 is provided to the power line 55N on a negative electrode side. The shunt resistor 54 is a metal plate-shaped resistor (see FIG. 10). The shunt resistor 54 can measure a current I of the assembled battery 60 based on a voltage Vr across both ends of the shunt resistor 54. Discharging of electricity or charging of electricity can be determined based on the polarity (positive or negative) of the end-to end voltage Vr. The shunt resistor 54 is an example of a “resistor for current measurement”. The temperature sensor 58 is mounted on the assembled battery 60, and detects a temperature of the assembled battery 60 or a temperature around the assembled battery 60.

The bypass circuit 110 includes a semiconductor switch 111 and a diode 113. As the semiconductor switch 111, an FET with a P channel can be used. A source S of the semiconductor switch 111 is connected to one end portion (point A) of the current interruption device 53.

An anode of the diode 113 is connected to a drain D of the semiconductor switch 111 and a cathode of the diode 113 is connected to the other end (point B) of the current interruption device 53. The forward direction of the diode 113 is a discharging direction of the assembled battery 60.

The bypass circuit 110 is connected in parallel to the current interruption device 53. In a state where the current interruption device 53 is in an open state, the assembled battery 60 can discharge electricity via a path that passes through the bypass circuit 110.

The discharge circuit 120 includes a discharge resistor 121 and a discharge switch 123. The discharge resistor 121 and the discharge switch 123 are connected in series. The discharge circuit 120 is connected in parallel to the current interruption device 53 and the assembled battery 60. One end of the discharge circuit 120 is connected to a connection point (point C) between the current interruption device 53 and the external terminal 51, and the other end of the discharge circuit 120 is connected to a connection point (point D) between the negative electrode of the assembled battery 60 and the shunt resistor 54.

The management device 130 is mounted on the circuit board 100 (see FIG. 2). As illustrated in FIG. 5, the management device 130 includes a CPU 131 and a memory 133. The management device 130 is an example of “a control device”.

The management device 130 is connected to the vehicle ECU 150 via a signal line, and communicates with the vehicle ECU 150. The management device 130 can receive signals relating to operation states of the vehicle 10 (traveling, stopping, parking and the like) from the vehicle ECU 150 by communication.

The management device 130 monitors the state of the battery 50 based on an output of the voltage detection (not illustrated in the drawing), an output of the shunt resistor 54, and an output of the temperature sensor 58. That is, the management device 130 monitors a temperature, a current I, and a total voltage V1 of the assembled battery 60. The management device 130 controls the current interruption device 53 based on a monitoring result of a state of the assembled battery 60.

The management device 130 is connected to the points A and B at both ends of the current interruption device via the signal lines La and Lb, and can detect an end-to-end voltage Vab of the current interruption device 53.

In an equation Vab=Va−Vb, Va indicates a voltage at point A, and Vb indicates a voltage at point B.

The memory 133 stores a monitoring program for monitoring the state of the battery 50, a failure diagnosis program of the current interruption device 53, and data necessary for executing these programs. The program may be stored in a recording medium such as a CD-ROM, and may be used, transferred, lent, or the like. The program may also be distributed using an electric communication line.

### 2. Diagnosis of Failure in Current Interruption Device

When a failure occurs in the current interruption device 53, the battery 50 cannot be protected from overdischarging or overcharging. Accordingly, it is necessary to diagnose the occurrence of a failure in the current interruption device 53.

In a case where the current interruption device 53 is normal, when the current interruption device 53 is controlled to take an open state in a state where the bypass circuit 110 and the discharge circuit 120 are closed, electricity is allowed to pass through the bypass circuit 110 so that the end-to-end voltage Vab of the current interruption device 53 becomes substantially equal to a breakdown voltage of the diode 113. On the other hand, when a failure has occurred in the current interruption device 53 (the current interruption device is not opened), the current interruption device 53 maintains a close state and hence, and the end-to-end voltage Vab of the current interruption device 53 is substantially 0.

In this manner, the end-to-end voltage Vab of the current interruption device 53 changes in response to the state of the current interruption device 53. Accordingly, the occurrence of a failure in the current interruption device 53 can be diagnosed based on the end-to-end voltage Vab of the current interruption device 53.

However, when a total voltage V1 of the assembled battery 60 and a voltage V2 of a power supply line LG of the vehicle 10 are substantially equally balanced (V1≈V2), the end-to-end voltage Vab is substantially 0 irrelevant to the state of the current interruption device 53. Accordingly, it is not possible to diagnose the occurrence of a failure in the current interruption device 53 using a value of the end-to-end voltage Vab.

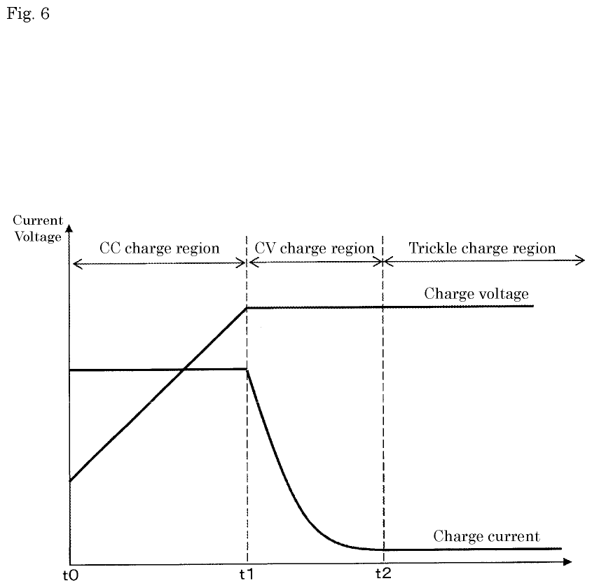

As a specific example of the case where V1≈V2, there is a case where the battery 50 is charged with electricity by connecting an external charger 200 to the connection terminals 11 and 12 of the vehicle 10. FIG. 6 illustrates charge characteristics of the battery 50 brought about by the external charger 200. The charge characteristics of the battery 50 include three charging regions of a CC charging region, a CV charging region, and a trickle charging region.

The CC charging region (t0 to t1) is a region for charging the battery 50 with a constant current. The voltage V1 of the battery 50 is increased substantially in proportion to time due to CC charging.

The CV charging region (t1 to t2) is a region in which, after the voltage V1 of the battery 50 increases to a set voltage by CC charging, the battery 50 is charged at a constant voltage until the battery 50 is fully charged. During CV charging, the charge current decreases and droops when the battery 50 reaches a point near a fully charged state.

The trickle charging region (after t2) is a charging method in which, after the battery 50 is charged to the fully charged state, a minute current is continuously made to flow to the battery 50 at an amount that does not affect the battery 50 so as to maintain the fully charged state of the battery 50 by compensating for the decrease in capacity caused by self-discharge or the like.

During trickle charging, the charging voltage of the external charger 200 is substantially equal to the total voltage V1 of the assembled battery 60. That is, a relationship of V1≈V2 exists. Accordingly, it is difficult to diagnose the occurrence of a failure in the current interruption device 53 based on the end-to-end voltage Vab of the current interruption device 53.

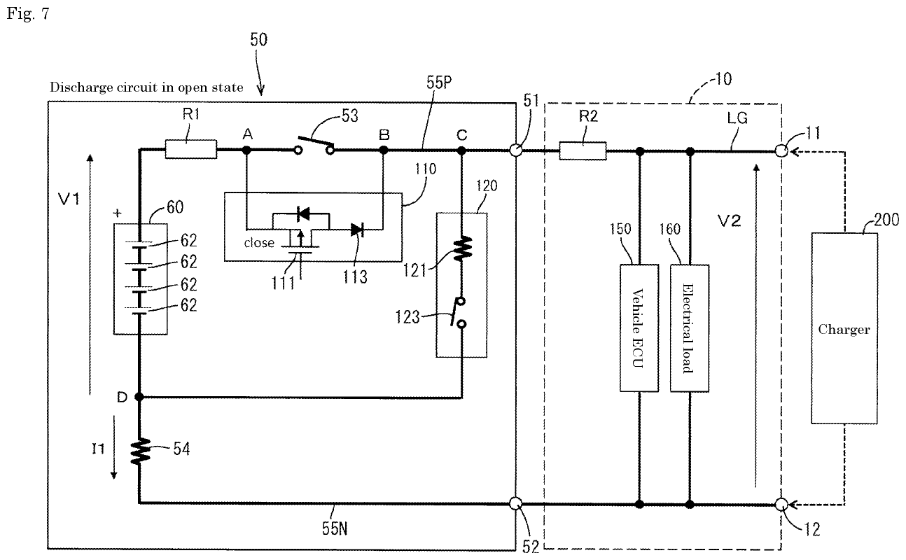

FIG. 7 illustrates a current path in the battery 50 when the current interruption device 53 is controlled to take an open state in a state where the semiconductor switch 111 of the bypass circuit 110 takes a closed position and the discharge switch 123 of the discharge circuit 120 takes an open position with a relationship of V1≈V2. In this case, irrelevant to the state of the current interruption device 53, substantially no current flows in the battery 50 and hence, a current I1 measured by the shunt resistor 54 is substantially 0.

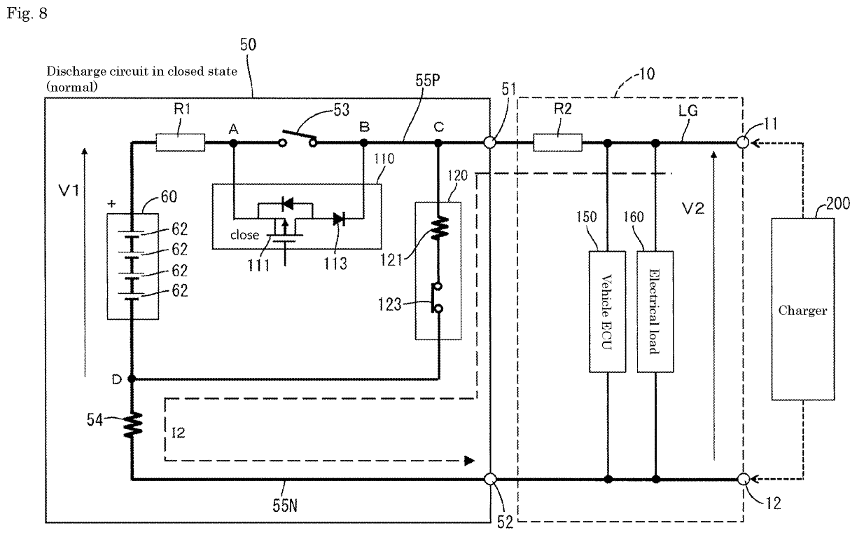

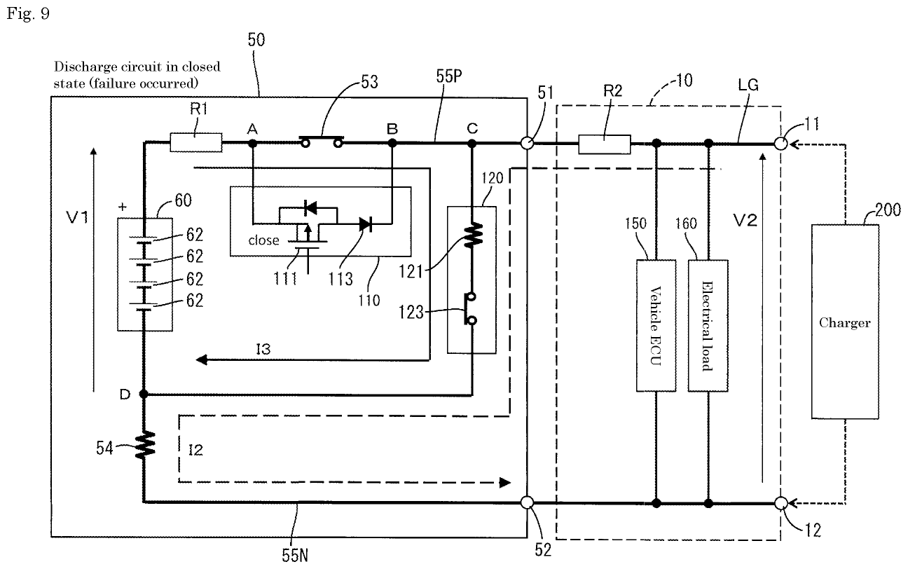

FIG. 8 and FIG. 9 illustrate a current path in the battery 50 when the discharge switch 123 of the discharge circuit 120 is changed over from an “open” position illustrated in FIG. 7 to a “closed” position.

When the current interruption device 53 is in an open state (a normal state illustrated in FIG. 8), the current I2 from the vehicle 10 flows through a path formed of the external terminal 51, the discharge circuit 120, the shunt resistor 54, and the external terminal 52.

When the current interruption device 53 is closed (a failure occurred: FIG. 9), the current I2 flows from the vehicle 10 through a path formed of the external terminal 51, the discharge circuit 120, the shunt resistor 54, and the external terminal 52, and further, a current I3 flows through the assembled battery 60, the current interruption device 53, and the discharge circuit 120.

When the current interruption device 53 is in a closed state (a failure occurred), the current I3 flows to the discharge circuit 120 in addition to the current I2. Accordingly, compared with the case where the current interruption device 53 is normal (FIG. 8), an amount of the current I2 that flows into the shunt resistor 54 decreases.

For example, under the following calculation conditions, the current I2 decreases to “51.8 mA” when the current interruption device 53 is in an open state (normal state), whereas the current I2 decreases to “4.7 mA” when the current interruption device 53 is in a closed state (a failure occurred).

### (Calculation Condition of Current I2)

A voltage at a point C is 14 V, a resistance of the discharge resistor 121 is 270Ω, a resistance of a structural resistor R1 of the battery 50 is 1 mΩ, a resistance of the wiring resistor R2 of the vehicle 10 is 10 mΩ, and a resistance of the shunt resistor 54 is 95μΩ.

### <In an Open State (FIG. 8)>

$$V 2 = I 2 \times ( 10 m Ω + 270 Ω + 95 μ Ω )$$

Substituting 14V for V2, I2 of 51.8 mA is obtained (I2=51.8 mA).

### <In a Closed State (FIG. 9)>

$$V 1 = I 3 \times 1 m Ω + ( I 2 + I 3 ) \times 270 Ω$$

$$V2 = I 2 \times 10 mΩ + ( I 2 + I 3 ) \times 270 Ω + I 2 \times 95 μΩ$$

Substituting 14 V for V1 and V2, I2 of 4.7 mA and I3 of 52 mA are obtained (I2=4.7 mA, I3=52 mA).

In the case of V1≈V2, since the voltage between both ends of R1 is equal to the voltage between both ends of R2, I2 and I3 have the following relationship, and the current value is determined by the resistance ratio between R1 and R2.

$$I 3 \times R 1 = I 2 \times R 2$$

When a relationship of R1<<R2 exists, a relationship of I3>>I2 exists. Therefore, the current I2 decreases to several mA when the current interruption device 53 is in a closed state, and becomes smaller than a value when the current interruption device 53 is in an open state.

In this manner, the current I2 that flows through the shunt resistor 54 changes depending on the state (the open state, the closed state) of the current interruption device 53, it is possible to determine the occurrence of a failure in the current interruption device 53 from the magnitude of the current I2.

### 3. Error in Current Measurement Due to Seebeck Effect

The Seebeck effect is a phenomenon in which an electromotive force is generated at both ends of an object due to a temperature difference ΔT generated between both ends of the object. As illustrated in FIG. 10, when a temperature difference ΔT is generated between both ends of the shunt resistor 54 for some reason, a voltage ΔV is generated between both ends of the shunt resistor 54 due to the Seebeck effect. As a result, an error occurs in measurement of a current I.

Since a relatively large resistance value is used for the discharge resistor 121 in order to suppress power consumption, the current I flowing from the assembled battery 60 or the external charger 200 to the discharge circuit 120 is a minute current of 50˜60 mA or less. Accordingly, in order to improve the accuracy of the diagnosis of the occurrence of a failure in the current interruption device 53, it is necessary to suppress an error in the measurement of the current I due to the shunt resistor 54.

The current I1 is a current measurement value in a state where no current flows in the battery 50. The current I2 and the current I1 respectively include an error in measurement of the current I due to the Seebeck effect. Accordingly, it is possible to cancel the current measurement error due to the Seebeck effect by obtaining a current difference value ΔI between the current I2 and the current I1. The current difference value ΔI is an example of a “difference between the current values”.

$$Δ I = I 2 - I 1$$

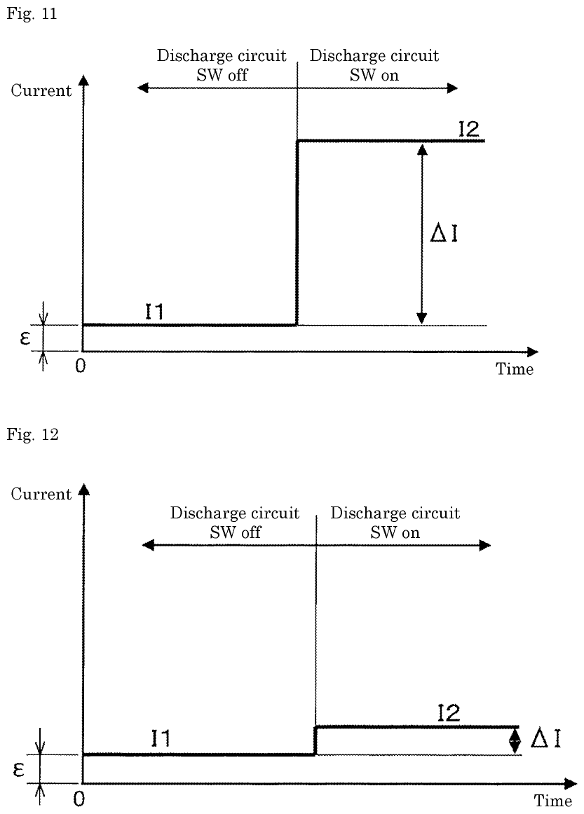

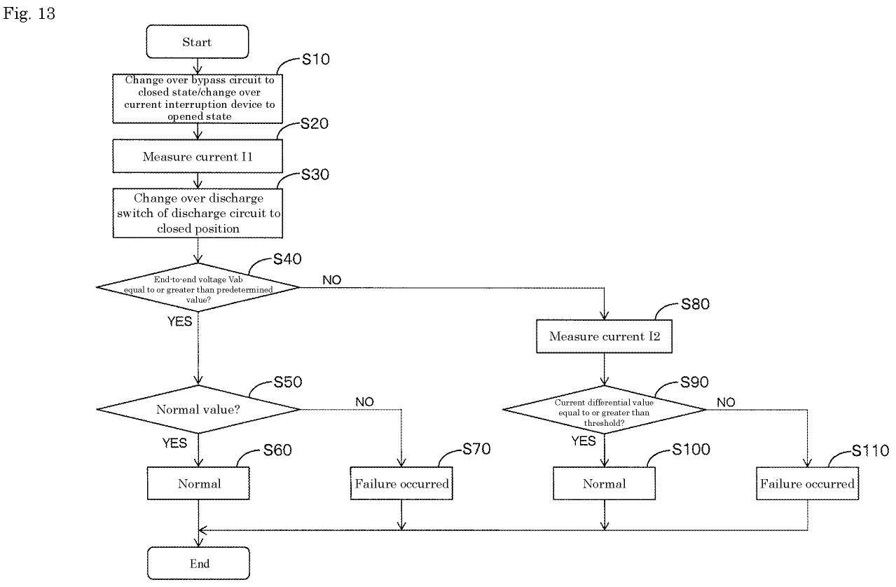

FIG. 11 is a graph illustrating a relationship between the current I1 and the current I2 when the current interruption device 53 is in an open state (normal state), and FIG. 12 is a graph illustrating a relationship between the current I1 and the current I2 when the current interruption device 53 is in a closed state (a failure occurred). “ε” is a current measurement error due to the Seebeck effect.

In this embodiment, the current difference value ΔI is compared with a threshold so as to perform a diagnosis of the occurrence of a failure in the current interruption device 53. When the current difference value ΔI is equal to or greater than the threshold, the current interruption device 53 is determined to be normal (an open state), and when the current difference value ΔI is less than the threshold, the current interruption device 53 is determined to have a failure (a closed state). The threshold is 10 mA as an example.

With the use of the current difference value ΔI, the current measurement error ε due to the Seebeck effect can be canceled and hence, the magnitude relationship between the current difference value ΔI and the threshold can be accurately determined. Accordingly, the accuracy of diagnosis of the occurrence of a failure in the current interruption device 53 can be enhanced.

### 4. Failure Diagnosis Sequence of Current Interruption Device 53

The failure diagnosis sequence of the current interruption device 53 is constituted of 11 steps, that is, step S10 to step S110. The failure diagnosis sequence is performed by the management device 130 when the following execution conditions are satisfied.

### (Implementation Conditions)

(A) −100 mA≤I≤0 A (negative implying discharge)
(B) The management device is in a sleep mode
(C) Predetermined day or more have elapsed since the previous diagnosis.

In the management device 130, two modes consisting of a “normal operation mode” and a “sleep mode” are set. The “sleep mode” is a mode where power consumption is lower than power consumption in the normal operation mode. In a case where a state in which the current I of the battery 50 is equal to or less than a predetermined value continues for a predetermined time such as a case where the vehicle 10 is being parked, the management device 130 shifts its operation mode from the normal operation mode to the sleep mode. The transition of the mode may be performed based on the magnitude of the current I or may be performed based on the presence or absence of communication with the vehicle ECU 150.

When the three conditions (A) to (C) are satisfied, the management device 130 performs the failure diagnosis sequence. Before the failure diagnosis is performed, the current interruption device 53 is controlled to take a closed state, the bypass circuit 110 is controlled to take an open state, and the discharge circuit 120 is controlled to take an open state.

When the failure diagnosis sequence starts, the management device 130 transmits a command to the bypass circuit 110 so as to change over the semiconductor switch 111 from an open position to a closed position. When the semiconductor switch 111 is changed over to the closed position, the management device 130 transmits a command to the current interruption device 53 so as to change over the current interruption device 53 from the closed state to the opened state (S10).

After transmitting the command to the current interruption device 53, the management device 130 measures the current I1 using the shunt resistor 54 (S20).

After measuring the current I1, the management device 130 transmits a command to the discharge circuit 120 so as to change over the discharge switch 123 from the open position to the closed position (S30).

After the position of the discharge switch 123 is changed over, the management device 130 measures the voltages Va and Vb at the points A and B disposed at both ends of the current interruption device, and detects an end-to-end voltage Vab of the current interruption device 53.

Then, the management device 130 determines whether the end-to-end voltage Vab is equal to or greater than a predetermined value. The predetermined value is a voltage lower than a breakdown voltage of the diode 113. For example, when the breakdown voltage is 0.6 V, the end-to-end voltage Vab is 0.3 V (S40).

When the end-to-end voltage Vab is equal to or greater than the predetermined value (YES in S40), the management device 130 determines whether the end-to-end voltage Vab is the normal value (S50). When the end-to-end voltage Vab is included within a predetermined range with reference to the breakdown voltage of the diode 113, the end-to-end voltage Vab is determined to be a normal value.

When the end-to-end voltage Vab is a normal value, the management device 130 determines that the current interruption device 53 is normal (in an open state) (S60).

On the other hand, when the end-to-end voltage Vab is not included within the predetermined range with respect to the breakdown voltage of the diode 113, the end-to-end voltage Vab is determined to be an abnormal value. When the end-to-end voltage Vab is an abnormal value, the management device 130 determines that a failure has occurred in the current interruption device 53 (S70).

Next, when the end-to-end voltage Vab of the current interruption device 53 is less than the predetermined value (NO in S40), the management device 130 measures the current I2 using the shunt resistor 54 (S80).

After the measurement of the current I2, the management device 130 calculates a current difference value ΔI from the “current I2” measured in step S80 and the “current I1” measured in step S20. The management device 130 compares the calculated current difference value ΔI with the threshold (S90). The threshold is 10 mA as an example.

When the current difference value ΔI is equal to or greater than the threshold, the management device 130 determines that the current interruption device 53 is normal (in an open state) (S100).

When the current difference value ΔI is less than the threshold, the management device 130 determines that a failure has occurred in the current interruption device 53 (in a closed state S110).

When a failure is detected in the current interruption device 53 (S70 and S110), the management device 130 notifies the vehicle ECU 150 of the occurrence of abnormality in the battery 50. Accordingly, it is possible to urge the early replacement of the battery 50.

### 5. Description of Advantageous Effects

In the configuration described above, by calculating the current difference value ΔI, it is possible to suppress a decrease in accuracy of current measurement due to the Seebeck effect. Accordingly, the accuracy of diagnosis of the occurrence of a failure in the current interruption device 53 can be enhanced.

With such a configuration, it is possible to detect a failure in the current interruption device 53 at an early stage and hence, and it is possible to urge the early replacement of the battery 50.

### Other Embodiments

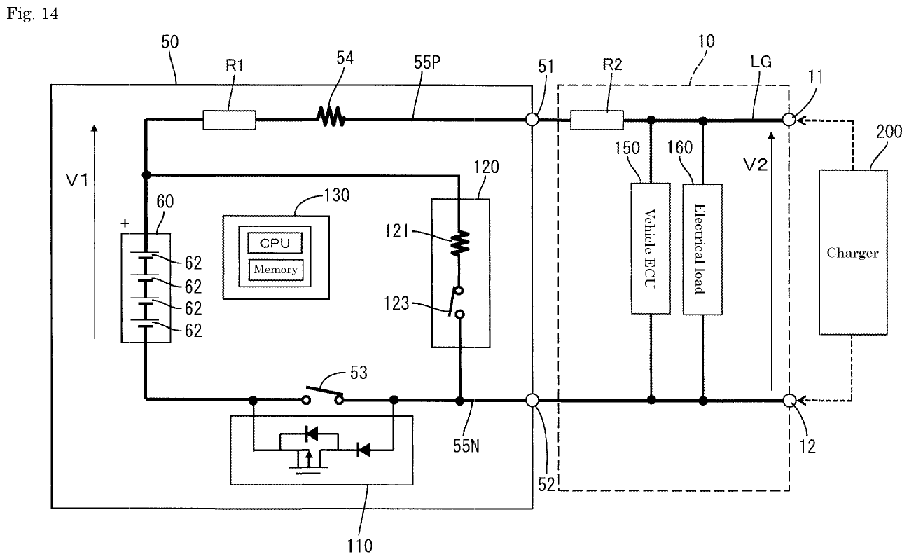

The present invention is not limited to the embodiments described with reference to the above description and drawings. For example, the following embodiments are also included in the technical scope of the present invention.
(1) The cell (repeatedly chargeable and dischargeable storage cell) 62 is not limited to the lithium ion secondary battery cell, and may be other nonaqueous electrolyte secondary battery cells. The connection of the cells 62 is not limited to the case where the cells 62 are connected in series and in parallel, and the cells 62 may be connected in series or a single cell may be used. A capacitor can be used instead of the secondary battery cell. The secondary battery cell and the capacitor are examples of the cell.
(2) In the above embodiment, the battery 50 is mounted on the vehicle 10. However, the battery 50 may be mounted on a moving body other than the vehicle such as a ship or an aircraft. Further, the application of the method of diagnosing a failure in the battery (energy storage apparatus) 50 or the current interruption device 53 is not limited to the moving body, and the method may be used for stationary applications such as an energy storage device for absorbing fluctuations in a distributed power generation system and an uninterruptible power system (UPS)
(3) In the above embodiment, the current interruption device 53 is provided to the power line 55P of the positive electrode, and the shunt resistor 54 is provided to the power line 55N of the negative electrode. As illustrated in FIG. 14, however, the shunt resistor 54 may be provided to the power line 55P of the positive electrode, and the current interruption device 53 may be provided to the power line 55N of the negative electrode. The bypass circuit 110 may be omitted.
(4) The present technique is not limited to the configuration disclosed in the embodiment, and can be widely applicable, as long as the calculation of the difference ΔI cancels the current measurement error & due to the Seebeck effect and improves the fault diagnosis accuracy of the current interrupter 53.

For example, in the above embodiment, the case has been described where the external charger 200 is connected to the battery 50. However, besides the above case, the present invention is applicable to a case where another power supply is connected in parallel to the battery 50. The present invention is not limited to the case where the battery 50 is trickle-charged, and is applicable to a case where the battery 50 mounted on the vehicle has no current (in a case where a current measurement value of the shunt resistor 54 is substantially zero in a state where the discharge switch 123 is turned off). In addition to the above-mentioned configuration, the present invention is also applicable to a case where the current value I2 measured by the shunt resistor 54 changes according to the state (the closed state or the open state) of the current interruption device 53 in a state where the discharge switch 123 is controlled to take a closed position.

1. An energy storage apparatus comprising:
a cell;
positive and negative external terminals;
a current interruption device that is disposed on a first line that connects the cell and one of the external terminals;
a resistor for current measurement that is disposed on a second line that connects the cell and the other of the external terminals;
a discharge circuit connected to the cell and the current interruption device in parallel; and
a control device,
wherein the discharge circuit includes:
a discharge resistor and
a discharge switch, and
the control device is configured, in a state where the current interruption device is controlled to take an open state,
to measure a current by the resistor with respect to a state where the discharge switch is controlled to take a closed position and a state where the discharge switch is controlled to take an open position, and
to diagnose a failure in the current interruption device based on a difference between a current value measured in a state where the discharge switch is controlled to take the closed position and a current value measured in a state where the discharge switch is controlled to take the open position.

2. The energy storage apparatus according to claim 1, wherein the control device is configured to determine that the current interruption device is normal in a case where the difference between the current values is equal to or greater than a threshold.

3. The energy storage apparatus according to claim 1, wherein the control device is configured to determine that a failure has occurred in the current interruption device in a case where the difference between the current values is less than a threshold.

4. A method of diagnosing a failure in a current interruption device used in an energy storage apparatus, wherein:
the energy storage apparatus includes:
a cell;
positive and negative external terminals;
a current interruption device that is disposed on a first line that connects the cell and one of the external terminals;
a resistor for current measurement that is disposed on a second line that connects the cell and the other of the external terminals; and
a discharge circuit connected to the cell and the current interruption device in parallel, and
the method comprising:
measuring a current by the resistor with respect to a state where the discharge switch of the discharge circuit is controlled to take a closed position and a state where the discharge switch is controlled to take an open position in a state where the current interruption device is controlled to take an open state, and
diagnosing a failure in the current interruption device based on a difference between a current value measured in a state where the discharge switch of the discharge circuit is controlled to take the closed position and a current value measured in a state where the discharge switch is controlled to take the open position.

5. The energy storage apparatus according to claim 2, wherein the control device is configured to determine that a failure has occurred in the current interruption device in a case where the difference between the current values is less than a threshold.
